(19) United States
(12) Patent Application Publication
(10) Pub. No.: US 2025/0237704 A1
(43) Pub. Date: Jul. 24, 2025

(54) BATTERY MANAGEMENT SYSTEM AND METHOD FOR CONTROLLING THE SAME

(71) Applicant: SK ON CO., LTD., Seoul (KR)

(72) Inventors: Kyu Min HWANG, Daejeon (KR); Won Hee KIM, Daejeon (KR); Myeong Jae GO, Daejeon (KR)

(21) Appl. No.: 19/025,953

(22) Filed: Jan. 16, 2025

(30) Foreign Application Priority Data
Jan. 23, 2024 (KR) 10-2024-0010462

(51) Int. Cl. G01R 31/367; G01R 31/36; G01R 31/374; G01R 31/3842; G01R 31/389; G01R 31/392

(52) U.S. Cl. CPC G01R 31/367; G01R 31/3646; G01R 31/374; G01R 31/3842; G01R 31/389; G01R 31/392

(57) ABSTRACT

The present disclosure relates to a battery management system and a method for controlling the same. The battery management system according to an embodiment of the present disclosure includes: an electrochemical impedance spectroscopy (EIS) measurement module configured to measure EIS of a secondary battery; a processor configured to receive an EIS measurement result from the EIS measurement module, calculate a real intercept and an inflection point of an impedance value for the secondary battery based on the received EIS measurement result, and extract an equivalent circuit model (ECM) parameter for the secondary battery based on the calculated real intercept and the calculated inflection point.

### CROSS-REFERENCE TO RELATED APPLICATION(S)

This patent document claims the priority and benefits of Korean Patent Application No. 10-2024-0010462 filed on Jan. 23, 2024, the disclosure of which is incorporated herein by reference in its entirety.

### BACKGROUND OF THE INVENTION

### 1. Field of the Invention

The present disclosure relates to a battery management system and a method for controlling the same.

### 2. Description of the Related Art

A secondary battery is a battery that can be repeatedly charged and discharged. With rapid progress of information and communication, and display industries, the secondary battery has been widely applied to various portable electronic telecommunication devices such as a camcorder, a mobile phone, a tablet personal computer (PC), a laptop PC, etc. as a power source thereof. Recently, a battery pack including the secondary battery has also been developed as a power source of an eco-friendly automobile such as an electric vehicle.

Meanwhile, the secondary battery includes a battery management system (BMS). The battery management system is capable of measuring and monitoring various information related to the secondary battery, such as a current, voltage, temperature, state of charge (SOC), depth of discharge, and/or state of health (SOH) of the battery through various sensors.

The battery management system can estimate a state of the secondary battery. For example, the battery management system may estimate the state of the secondary battery using an equivalent circuit model (ECM) estimation module. The ECM estimation module may estimate an ECM parameter using voltage changes according to current changes. However, since there is no change in the current in a rest period between charge and discharge and a constant current operation section of the secondary battery, it is difficult to accurately estimate the ECM parameter in the rest period and the constant current operation section.

### SUMMARY OF THE INVENTION

According to one aspect of the present disclosure, it is an object to provide a battery management system and a method for controlling the same capable of improving accuracy and/or efficiency in estimation of the state of a secondary battery.

According to another aspect of the present disclosure, it is an object to provide a battery management system and a method for controlling the same which may easily estimate the state of a secondary battery throughout the entire operation section of the secondary battery.

The battery management system and method for controlling the same of the present disclosure may be widely applied to green technology fields such as an electric vehicle, and a battery charging station, as well as other solar power generation and wind power generation using the batteries. In addition, the battery management system and method for controlling the same of the present disclosure may be used in an eco-friendly electric vehicle, and a hybrid vehicle, etc., which are intended to prevent climate change by suppressing air pollution and greenhouse gas emissions.

To achieve the above objects, according to an aspect of the present invention, there is provided a battery management system, including: an electrochemical impedance spectroscopy (EIS) measurement module configured to measure EIS of a secondary battery; and a processor configured to receive an EIS measurement result from the EIS measurement module, calculate a real intercept and an inflection point of an impedance value for the secondary battery based on the received EIS measurement result, and extract an equivalent circuit model (ECM) parameter for the secondary battery based on the calculated real intercept and the calculated inflection point.

According to an embodiment, the EIS measurement module may measure the EIS in units of battery cells or battery modules.

According to an embodiment, the processor may convert imaginary parts and real parts of the impedance value of the secondary battery according to the received EIS measurement result into a Nyquist plot in which the imaginary parts and the real parts are expressed on a vertical axis and a horizontal axis, respectively, and calculate the real intercept and the inflection point based on the converted Nyquist plot.

According to an embodiment, the processor may select a first point having a positive minimum value and a second point having a negative maximum value among the imaginary parts of the impedance value, and calculate the real intercept using coordinate values of the first point, coordinate values of the second point, and a designated equation.

According to an embodiment, the processor may calculate a slope of neighboring points on the Nyquist plot, and extract a point where a sign of the calculated slope changes from positive to negative in a low-frequency direction as the inflection point.

According to an embodiment, the ECM parameter may include a first resistor, a second resistor connected in series with the first resistor, and a capacitor connected in series with the first resistor and in parallel with the second resistor, and wherein the processor may determine the real intercept as a resistance value of the first resistor, calculate a resistance value of the second resistor based on a difference between the real value of the inflection point and the real intercept, and calculate a capacity value of the capacitor based on a frequency of the inflection point and the second resistor, or calculate a capacity value of the capacitor based on the second resistor and a time constant of the secondary battery.

According to an embodiment, the processor may monitor a change in the real intercept, and if the extracted real intercept is greater than a previously stored initial real intercept by a designated multiple or more, determine that the secondary battery is at an end of life (EOL).

According to an embodiment, the designated multiple may have a range of 1.7 to 2.0.

According to an embodiment, the battery management system may further include an alarm module configured to provide an alarm in a designated manner, wherein the processor may control the alarm module to alarm the end of life of the secondary battery.

According to an embodiment, the battery management system may further include an ECM estimation module configured to estimate an ECM parameter based on a voltage change according to a current change.

According to another aspect of the present invention, there is provided a method for controlling a battery management system, the method including: measuring electrochemical impedance spectroscopy (EIS) of a secondary battery through an EIS measurement module; calculating a real intercept and an inflection point of an impedance value for the secondary battery based on the measured EIS; and extracting an equivalent circuit model (ECM) parameter for the secondary battery based on the calculated real intercept and the calculated inflection point.

According to an embodiment, the step of calculating a real intercept and an inflection point may convert imaginary parts and real parts of the impedance value of the secondary battery into a Nyquist plot in which the imaginary parts and the real parts are expressed on a vertical axis and a horizontal axis, respectively, and calculate the real intercept and the inflection point based on the converted Nyquist plot.

According to an embodiment, the step of calculating a real intercept may select a first point having a positive minimum value and a second point having a negative maximum value among the imaginary parts of the impedance value, and calculate the real intercept using coordinate values of the first point, coordinate values of the second point, and a designated equation.

According to an embodiment, the step of extracting as an inflection point may calculate a slope of neighboring points on the Nyquist plot, and extract a point where a sign of the calculated slope changes from positive to negative in a low-frequency direction as the inflection point.

According to an embodiment, the ECM parameter may include a first resistor, a second resistor connected in series with the first resistor, and a capacitor connected in series with the first resistor and in parallel with the second resistor, wherein a resistance value of the first resistor may correspond to the real intercept, a resistance value of the second resistor may be calculated based on a difference between the real value of the inflection point and the real intercept, and a capacity value of the capacitor may be calculated based on a frequency of the inflection point and the second resistor, or be calculated based on the second resistor and a time constant of the secondary battery.

According to an embodiment, the method may further include: monitoring a change in the real intercept; and if the extracted real intercept is greater than a previously stored initial real intercept by a designated multiple or more, determining that the secondary battery is at an end of life (EOL).

According to an embodiment, the method may further include controlling an alarm module to alarm the end of life of the secondary battery.

According to an embodiment, the designated multiple may have a range of 1.7 to 2.0.

According to an embodiment, the step of measuring EIS of the secondary battery may measure the EIS in units of battery cells or battery modules.

According to an embodiment, the method may further include estimating an ECM parameter based on a voltage change according to a current change through an ECM estimation module.

According to an embodiment of the present disclosure, the accuracy and/or efficiency in estimation of the state of a secondary battery may be improved. For example, the present disclosure may accurately and efficiently estimate the state of a secondary battery by extracting an ECM parameter based on the EIS measurement result.

In addition, the present disclosure may estimate the state of a secondary battery in entire operation section of the secondary battery by using the EIS measurement result. For example, the present disclosure may accurately estimate the state of a secondary battery even in the rest period and constant current operation section of the secondary battery to which it was difficult to apply the ECM estimation method. In other words, the present disclosure may complement vulnerabilities in the ECM estimation method.

In addition, the present disclosure may accurately and easily determine an end of life (EOL) of the secondary battery. For example, the present disclosure may accurately and easily determine the end of life of the secondary battery by monitoring a change in the real intercept.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a block diagram illustrating the configuration of a battery management system according to an embodiment of the present disclosure;

FIG. 2 is a flowchart for describing procedures of a method for controlling a battery management system according to an embodiment of the present disclosure;

FIG. 3A is a diagram for describing a method for extracting a real intercept according to an embodiment of the present disclosure;

FIG. 3B is a diagram for describing a method for extracting a real intercept according to another embodiment of the present disclosure;

FIG. 4 is a diagram for describing a method for extracting an inflection point according to an embodiment of the present disclosure;

FIG. 5 is a Nyquist plot illustrating an impedance of the secondary battery depending on an EIS measurement result according to an embodiment of the present disclosure;

FIG. 6 is a diagram illustrating equivalent circuit model (ECM) parameters calculated based on the EIS measurement result according to an embodiment of the present disclosure; and

FIG. 7 is a flowchart for describing procedures of a method for controlling a battery management system according to another embodiment of the present disclosure.

### DETAILED DESCRIPTION OF THE INVENTION

Hereinafter, the present disclosure will be described in detail through embodiments with reference to the accompanying drawings. However, the embodiments are merely illustrative and the present disclosure is not limited to the specific embodiments described by way of example.

Although a first, a second, and the like are used to describe various elements, components and/or sections, these elements, components and/or sections are of course not limited by these terms. These terms are merely used to distinguish one element, component and/or section from another element, component and/or section. Therefore, it goes without saying that the first element, first component or first section mentioned below may also be the second element, second component or second section within the technical spirit of the present disclosure.

Terms used herein are for the purpose of describing particular embodiments only and are not intended to limit the present disclosure thereto. As used herein, singular forms are intended to include the plural forms as well, unless the context clearly indicates otherwise. It will be further understood that the terms “comprises” and/or “made of,” as used herein, do not preclude the presence or addition of one or more components, steps, operations and/or elements other than those mentioned component, step, operation and/or element.

Unless otherwise defined, all terms (including technical and scientific terms) used herein have the same meaning as commonly understood by one of ordinary skill in the art to which the present disclosure pertains. Terms, such as those defined in commonly used dictionaries, are not to be construed in an idealized or overly formal sense unless expressly so defined herein.

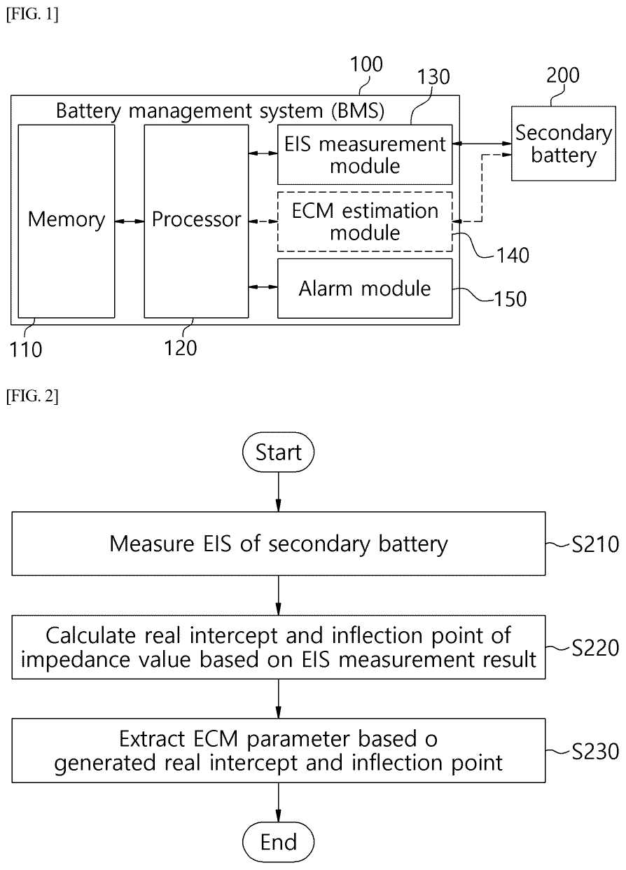

FIG. 1 is a block diagram illustrating the configuration of a battery management system according to an embodiment of the present disclosure.

Referring to FIG. 1, a battery management system 100 according to an embodiment of the present disclosure may monitor and/or manage a state of a secondary battery 200. According to an embodiment, the battery management system 100 may estimate the state of the secondary battery 200.

According to an embodiment, the secondary battery 200 may be charged. The secondary battery 200 may be a battery module including a plurality of battery cells or a battery pack including a plurality of battery modules. The secondary battery 200 may include a lithium iron phosphate (LFP, LiFePo₄) battery, a nickel cobalt manganese (NCM) battery or the like. The secondary battery 200 may be included in a device (e.g., an energy storage system (ESS), an electric vehicle, a hybrid vehicle, etc.) driven using the power of the secondary battery 200.

According to an embodiment, the battery management system 100 may include a memory 110, a processor 120, an electrochemical impedance spectroscopy (EIS) measurement module 130, an equivalent circuit model (ECM) estimation module 140, and an alarm module 150.

The EIS measurement module 130 may apply a variable frequency (e.g., a current signal of a sine wave) whose frequency changes in a designated range (e.g., 1 Hz to 1 KHz) with a designated magnitude (e.g., an amplitude corresponding to 2% of a capacity of the secondary battery 200) to the secondary battery 200, receive a voltage signal output from the secondary battery 200, and analyze the received voltage signal to measure an impedance change of the secondary battery 200. In other words, the EIS measurement module 130 may measure the impedance of the secondary battery 200 according to the frequency change. The impedance change of the secondary battery 200 according to the measurement results of the EIS measurement module 130 may be expressed as a Nyquist plot in an orthogonal coordinate system or a polar coordinate system. The Nyquist plot may represent a negative imaginary part (−Im(Z)) of the impedance value of the secondary battery 200 as a vertical axis (e.g., Y-axis) and a real part (Re(Z)) as a horizontal axis (e.g., X-axis).

The EIS measurement module 130 may measure EIS in units of battery cells or battery modules constituting the secondary battery 200. The EIS measurement module 130 may measure EIS in an entire operation section (e.g., constant current operation section, composite current operation section, and rest period (or zero current operation section)).

The processor 120 may control an operation of the battery management system 100. For example, the processor 120 may receive an EIS measurement result from the EIS measurement module 130, calculate a real intercept and an inflection point of an impedance value for the secondary battery 200 based on the received EIS measurement result, and extract an equivalent circuit model (ECM) parameter for the secondary battery 200 based on the calculated real intercept and the calculated inflection point. A specific operation of the processor 120 will be described in detail below with reference to FIGS. 2 to 6.

In addition, the processor 120 may monitor a change in a real intercept calculated based on the EIS measurement result, and if the monitored current real intercept is greater than a previously stored initial real intercept by a designated multiple (e.g., 1.7 to 2.0 times) or more, determine that an abnormality has occurred in the secondary battery 200 (e.g., the secondary battery 200 has reached the end of its lifetime), and control the alarm module 150 to provide an alarm (e.g., an end of life (EOL) alarm of the secondary battery 200). A specific operation of the processor 120 will be described in detail below with reference to FIG. 7.

In addition, the processor 120 may complement the measurement result of the EIS measurement module 130 and the estimation result of the ECM estimation module 140 in conjunction with each other, and more accurately estimate or calculate the ECM parameter for the secondary battery 200. For example, the ECM parameter may change depending on the deterioration of the secondary battery 200. For example, if an initial value of a first resistor is 1 mΩ, it is discharging with a current of 100 A, and a discharge voltage of the battery is 3.0 V, an open circuit voltage (OCV) of the secondary battery is 3.1 (=discharge voltage (3.0 V)+(discharge current (100 A)*resistance (0.001Ω))) V. However, if the resistance value of the first resistor is increased due to the deterioration of the secondary battery 200, an error (or failure), in which the open circuit voltage (OCV) of the secondary battery is increased, will occur. Accordingly, the present disclosure may correct (or modify) the error by updating the ECM parameter estimated by the ECM estimation module 140 with the ECM parameter extracted by the EIS measurement module 130.

The memory 110 may store a program that controls an operation of the battery management system 100. In addition, the memory 110 may store information necessary to control the operation of the battery management system 100. For example, the memory 110 may store a program that extracts the ECM parameter for the secondary battery 200 based on the EIS measurement result, a program that monitors a change in the real intercept and the like. In addition, the memory 110 may store a calculation formula for calculating the inflection point, a calculation formula for calculating the real intercept and the like. Further, the memory 110 may store an initial real intercept. The initial real intercept may correspond to a series resistance (or a first resistance) among the ECM parameters calculated when a state of health (SOH) of the secondary battery 200 is 100%.

The alarm module 150 may provide an alarm to notify that there is an abnormality in the secondary battery 200 (e.g., end of life of the secondary battery 200). The alarm module 150 may provide at least one of a visual alarm (e.g., light emitting diode (LED) lighting, icon display, pop-up window display, etc.), an auditory alarm (e.g., sound effect output), and a tactile alarm (e.g., vibration generation). The alarm module 150 may include at least one of a light emitting diode, a display, a speaker, and a vibration motor.

The ECM estimation module 140 may measure a current and a voltage of the secondary battery 200, and estimate the ECM parameter for the secondary battery 200 based on a voltage change according to a current change. According to an embodiment, the ECM estimation module 140 may operate in a partial operation section (e.g., a composite current operation section) among the operation sections of the secondary battery 200. Meanwhile, when extracting the ECM parameter of the secondary battery 200 using only EIS measurement result, the ECM estimation module 140 may be omitted.

Meanwhile, although not shown in the drawings, the battery management system 100 according to an embodiment of the present disclosure may estimate the ECM parameter of the secondary battery 200 in conjunction with the EIS measurement module 130 and the ECM estimation module 140 each other. For example, the battery management system 100 may extract an ECM parameter using the EIS measurement module 130 in the rest period and constant current operation section among the operation sections of the secondary battery 200, and may estimate the ECM parameter using the ECM estimation module 140 in the composite current operation section. Through this, the present disclosure may complement the vulnerabilities in the conventional ECM-based estimation method in which it was difficult to estimate impedances in the rest period and constant current operation section.

In addition, the battery management system 100 according to an embodiment of the present disclosure may not include some of the above-described configurations (e.g., the ECM estimation module 140, and the alarm module 150), or may further include at least one other component (e.g., a display, a communication module, etc.).

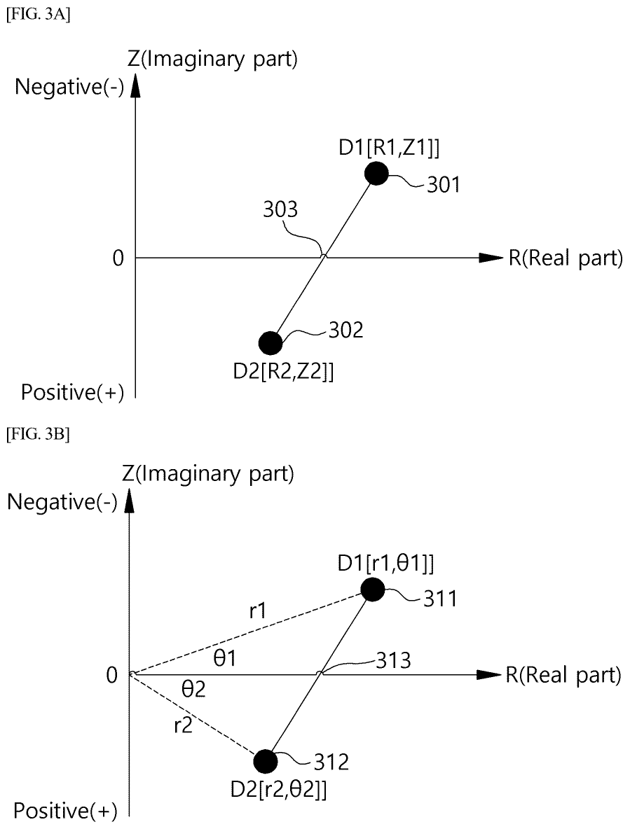

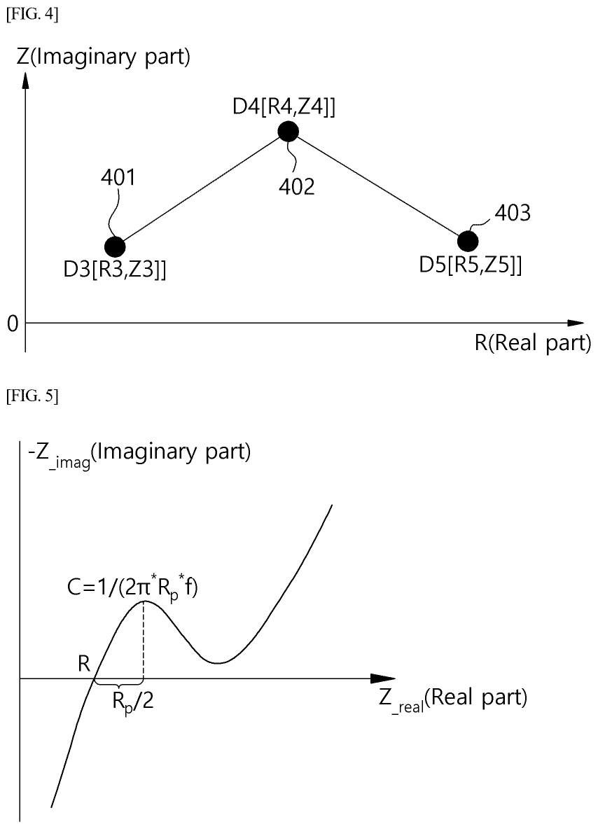

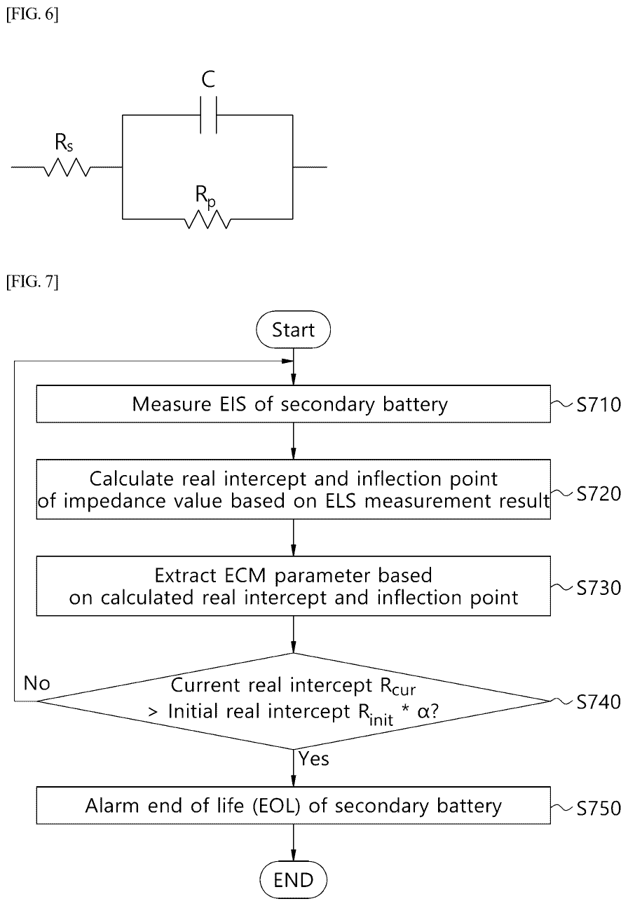

FIG. 2 is a flowchart for describing procedures of a method for controlling a battery management system according to an embodiment of the present disclosure, FIG. 3A is a diagram for describing a method for extracting a real intercept according to an embodiment of the present disclosure, FIG. 3B is a diagram for describing a method for extracting a real intercept according to another embodiment of the present disclosure, FIG. 4 is a diagram for describing a method for extracting an inflection point according to an embodiment of the present disclosure, FIG. 5 is a Nyquist plot illustrating an impedance of the secondary battery depending on an EIS measurement result according to an embodiment of the present disclosure, and FIG. 6 is a diagram illustrating equivalent circuit model (ECM) parameters calculated based on the EIS measurement result according to an embodiment of the present disclosure.

Referring to FIGS. 2 to 6, the method for controlling a battery management system (hereinafter, the control method) according to an embodiment of the present disclosure may include a step S210 of measuring EIS of the secondary battery. For example, the processor 120 of the battery management system 100 may measure EIS of the secondary battery 200 using the EIS measurement module 130. The EIS measurement module 130 may apply a variable frequency in a designated range with a designated magnitude to the secondary battery 200 as an input signal, and measure an output signal of the secondary battery 200. According to an embodiment, the EIS measurement module 130 may measure EIS in units of battery cells or battery modules. For example, the EIS measurement module 130 may measure EIS in units of battery cells when the secondary battery 200 is a battery module, and may measure EIS in units of battery modules when the secondary battery 200 is a battery pack.

According to an embodiment, the step of measuring EIS of the secondary battery 200 in the step S210 may be performed during operation of a device (e.g., an energy storage system (ESS), an electric vehicle, a hybrid vehicle, etc.) including the secondary battery 200.

The control method may include a step S220 of calculating a real intercept and an inflection point of impedance values for the secondary battery based on the EIS measurement result.

The real intercept may be a value related to internal resistance (e.g., electrode resistance+electrolyte resistance) characteristics among the EIS measurement results. The processor 120 may express the impedance values as a Nyquist plot of an orthogonal coordinate system or a polar coordinate system, and may calculate the real intercepts of the impedance values using the Nyquist plot of the orthogonal coordinate system or the polar coordinate system. For example, when the impedance values are expressed as a Nyquist plot of the orthogonal coordinate system, the processor 120 may generate a straight line equation connecting a first point 301 having a positive minimum value and a second point 302 having a negative maximum value among imaginary parts of the impedance values, as shown in FIG. 3A, and calculate a real intercept 303 using the generated straight line equation. Here, a straight line equation Z may be generated as in <Equation 1> below, and the real intercept 303 may be calculated by <Equation 2> below.

$$Straight line equation ( Z ) = Z 1 + ( \frac{Z 1 - Z 2}{R 1 - R 2} ) ( R - R 1 ) \qquad < Equation 1 >$$

$$Real intercept R = R 1 - ( \frac{R 1 - R 2}{Z 1 - Z 2} ) ( Z 1 ) \qquad < Equation 2 >$$

As another example, when the impedance values are expressed as a Nyquist plot of the polar coordinate system, as shown in FIG. 3B, the processor 120 may generate the straight line equation Z connecting the third point 311 and a fourth point 312 as <Equation 3> below, and calculate a real intercept 313 by <Equation 4> below.

$$Straight line equation ( Z ) = r 1 sin θ1 + ( \frac{r 1 sin θ1 - r 2 sin θ2}{r 1 cos θ1 - r 2 cos θ2} ) ( R - r 1 cos θ1 ) \qquad < Equation 3 >$$

$$Real intercept R = r 1 cos θ1 - ( \frac{r 1 cos θ1 - r 2 cos θ2}{r 1 sin θ1 - r 2 sin θ2} ) ( r 1 sin θ1 ) \qquad < Equation 4 >$$

According to some embodiments, the processor may calculate the real intercept 303 or 313 using the coordinate values of the first point 301 (or the third point 311), the coordinate values of the second point 302 (or the fourth point 312), and a designated equation (e.g., <Equation 2> or <Equation 4>).

The inflection point may be a point where a slope changes. For example, the processor 120 may calculate (or extract) a slope of neighboring points on the Nyquist plot of the orthogonal coordinate system, and extract a point where a sign of the calculated slope changes inversely (e.g., from positive to negative) in a direction in which the EIS measurement frequency decreases (e.g., in a low-frequency direction (in a right direction based on FIG. 4)) as the inflection point. Specifically, the processor 120 may calculate a first slope between a fifth point 401 and a sixth point 402, and a second slope between the sixth point 402 and a seventh point 403, as shown in FIG. 4, and extract the sixth point 402 where the sign of the calculated slope changes inversely (e.g., from positive to negative) as the inflection point. Here, the first slope and the second slope may be calculated by <Equation 5> and <Equation 6> below.

$$First slope = ( Z 3 - Z 4 ) / ( R 3 - R 4 ) \qquad < Equation 5 >$$

$$Second slope = ( Z 4 - Z 5 ) / ( R 4 - R 5 ) \qquad < Equation 6 >$$

Meanwhile, when the impedance values are converted into a Nyquist plot of the polar coordinate system, the processor 120 may convert from polar coordinates to orthogonal coordinates using a designated equation, and may convert the impedance values into a Nyquist plot of the orthogonal coordinate system based on the converted orthogonal coordinates. Here, the equation for converting from the polar coordinates to the orthogonal coordinates is obvious to those skilled in the art, therefore will not be described in detail.

The control method may include a step S230 of extracting an ECM parameter based on the generated real intercept and inflection point. For example, the processor 120 may extract an ECM parameter using coordinates of the real intercept and inflection point extracted from the Nyquist plot of FIG. 5. Here, the ECM parameter may include a series resistor (hereinafter, a first resistor) Rs, and an RC circuit connected in series with the first resistor Rs, as shown in FIG. 6. The RC circuit may include a second resistor Rp and a capacitor C connected in parallel.

Values of the first resistor Rs, the second resistor Rp, and the capacitor C may be calculated by <Equation 7>, <Equation 8>, and <Equation 9> below, respectively.

$$First resistor Rs = Real intercept R \qquad < Equation 7 >$$

$$Second resistor Rp = ( Real value of inflection point - Real intercept ) * 2 \qquad < Equation 8 >$$

$$Capacitor C = 1 / ( 2 π * Rp * f ( Frequency of inflection point ) ) \qquad < Equation 9 >$$

According to some embodiments, the capacitor C may be calculated based on a time constant (τ(tau)) of the secondary battery. For example, the capacitor C may be calculated by <Equation 10> below.

$$Capacitor C = Time constant ( τ ) / Rp \qquad < Equation 10 >$$

The time constant (τ) may be calculated based on a rate at which the voltage is recovered during the rest period of the secondary battery. For example, the time constant (τ) may correspond to the time at which a voltage change amount (e.g., 63.2 mV) corresponding to 63.2% of a total voltage change amount (e.g., 100 mV) recovered during the rest period occurs.

Meanwhile, although not shown in the drawings, the battery management system 100 may estimate various information (e.g., the state of charge (SOC), depth of discharge, and/or state of health (SOH)) related to the secondary battery 200 based on the calculated ECM parameter, and may monitor and/or manage the state of the secondary battery based on the estimated information.

FIG. 7 is a flowchart for describing procedures of a method for controlling a battery management system according to another embodiment of the present disclosure.

Referring to FIG. 7, the method for controlling a battery management system according to another embodiment of the present disclosure (hereinafter, the control method) may include a step S710 of measuring EIS of the secondary battery, a step S720 of calculating a real intercept and an inflection point of an impedance value for the secondary battery based on the EIS measurement result, and a step S730 of extracting an ECM parameter based on the calculated real intercept and inflection point. Here, steps S710, S720 and S730 are the same as steps S210, S220 and S230 of FIG. 2, respectively, and therefore will not be described in detail.

The control method may include a step S740 of checking whether a current real intercept R_{cur} (or a first resistance Rs) is greater than an initial real intercept Rᵢₙᵢₜ by a designated multiple α or more. For example, the processor 120 may monitor (e.g., periodically or continuously) a change in the real intercept R (or the first resistance Rs), and determine whether the current real intercept R_{cur} (or the first resistance Rs) is greater than the initial real intercept Rᵢₙᵢₜ by the designated multiple α or more. Here, the initial real intercept Rᵢₙᵢₜ may correspond to the real intercept (or the first resistance Rs) when the state of health (SOH) of the secondary battery is 100%. The designated multiple may be selected within a range of 1.7 to 2.0.

As a result of the check in the step S740, if the current real intercept R_{cur} is not greater than the initial real intercept Rᵢₙᵢₜ by the designated multiple α or more, the control method may return to the step S710 and repeat the above-described process. On the other hand, as a result of the check in the step S740, if the current real intercept R_{cur} is greater than the initial real intercept Rᵢₙᵢₜ by the designated multiple α or more, the control method may perform a step S750 of alarming an end of life (EOL) of the secondary battery. For example, the processor 120 may display a message and/or icon for alarming the end of life (EOL) of the secondary battery on the display (or transmit it to an external device through a communication module), or output a designated sound effect through a speaker (not shown).

The contents described above are merely an example to which the principles of the present disclosure are applied, and other configurations may be further included in the present disclosure without departing from the scope of the present invention.

What is claimed is:

1. A battery management system, comprising:
an electrochemical impedance spectroscopy (EIS) measurement module configured to measure EIS of a secondary battery; and
a processor configured to receive an EIS measurement result from the EIS measurement module, calculate a real intercept and an inflection point of an impedance value for the secondary battery based on the received EIS measurement result, and extract an equivalent circuit model (ECM) parameter for the secondary battery based on the calculated real intercept and the calculated inflection point.

2. The battery management system according to claim 1, wherein the EIS measurement module measures the EIS in units of battery cells or battery modules.

3. The battery management system according to claim 1, wherein the processor converts imaginary parts and real parts of the impedance value of the secondary battery according to the received EIS measurement result into a Nyquist plot in which the imaginary parts and the real parts are expressed on a vertical axis and a horizontal axis, respectively, and calculates the real intercept and the inflection point based on the converted Nyquist plot.

4. The battery management system according to claim 3, wherein the processor selects a first point having a positive minimum value and a second point having a negative maximum value among the imaginary parts of the impedance value, and calculates the real intercept using coordinate values of the first point, coordinate values of the second point, and a designated equation.

5. The battery management system according to claim 3, wherein the processor calculates a slope of neighboring points on the Nyquist plot, and extracts a point where a sign of the calculated slope changes from positive to negative in a low-frequency direction as the inflection point.

6. The battery management system according to claim 1, wherein the ECM parameter comprises a first resistor, a second resistor connected in series with the first resistor, and a capacitor connected in series with the first resistor and in parallel with the second resistor, and
wherein the processor determines the real intercept as a resistance value of the first resistor,
calculates a resistance value of the second resistor based on a difference between the real value of the inflection point and the real intercept, and
calculates a capacity value of the capacitor based on a frequency of the inflection point and the second resistor, or calculates a capacity value of the capacitor based on the second resistor and a time constant of the secondary battery.

7. The battery management system according to claim 1, wherein the processor monitors a change in the real intercept, and
if the extracted real intercept is greater than a previously stored initial real intercept by a designated multiple or more, determines that the secondary battery is at an end of life (EOL).

8. The battery management system according to claim 7, wherein the designated multiple has a range of 1.7 to 2.0.

9. The battery management system according to claim 7, further comprising an alarm module configured to provide an alarm in a designated manner,
wherein the processor controls the alarm module to alarm the end of life of the secondary battery.

10. The battery management system according to claim 1, further comprising an ECM estimation module configured to estimate an ECM parameter based on a voltage change according to a current change.

11. A method for controlling a battery management system, the method comprising:
measuring electrochemical impedance spectroscopy (EIS) of a secondary battery through an EIS measurement module;
calculating a real intercept and an inflection point of an impedance value for the secondary battery based on the measured EIS; and
extracting an equivalent circuit model (ECM) parameter for the secondary battery based on the calculated real intercept and the calculated inflection point.

12. The method according to claim 11, wherein the step of calculating a real intercept and an inflection point converts imaginary parts and real parts of the impedance value of the secondary battery into a Nyquist plot in which the imaginary parts and the real parts are expressed on a vertical axis and a horizontal axis, respectively, and calculates the real intercept and the inflection point based on the converted Nyquist plot.

13. The method according to claim 12, wherein the step of calculating a real intercept selects a first point having a positive minimum value and a second point having a negative maximum value among the imaginary parts of the impedance value, and calculates the real intercept using coordinate values of the first point, coordinate values of the second point, and a designated equation.

14. The method according to claim 12, wherein the step of extracting as an inflection point calculates a slope of neighboring points on the Nyquist plot, and extracts a point where a sign of the calculated slope changes from positive to negative in a low-frequency direction as the inflection point.

15. The method according to claim 11, wherein the ECM parameter comprises a first resistor, a second resistor connected in series with the first resistor, and a capacitor connected in series with the first resistor and in parallel with the second resistor,
wherein a resistance value of the first resistor corresponds to the real intercept,
a resistance value of the second resistor is calculated based on a difference between the real value of the inflection point and the real intercept, and
a capacity value of the capacitor is calculated based on a frequency of the inflection point and the second resistor, or is calculated based on the second resistor and a time constant of the secondary battery.

16. The method according to claim 11, further comprising:
monitoring a change in the real intercept; and
if the extracted real intercept is greater than a previously stored initial real intercept by a designated multiple or more, determining that the secondary battery is at an end of life (EOL).

17. The method according to claim 16, further comprising controlling an alarm module to alarm the end of life of the secondary battery.

18. The method according to claim 16, wherein the designated multiple has a range of 1.7 to 2.0.

19. The method according to claim 11, wherein the step of measuring EIS of the secondary battery measures the EIS in units of battery cells or battery modules.

20. The method according to claim 11, further comprising estimating an ECM parameter based on a voltage change according to a current change through an ECM estimation module.
